(19) United States
(12) Patent Application Publication
(10) Pub. No.: US 2019/0355840 A1
(43) Pub. Date: Nov. 21, 2019

(54) SEMICONDUCTOR DEVICE AND METHOD FOR MANUFACTURING SEMICONDCUTOR DEVICE

(71) Applicant: ROHM CO., LTD., Kyoto-shi, Kyoto (JP)

(72) Inventors: Seigo MORI, Kyoto-shi (JP); Masatoshi AKETA, Kyoto-shi (JP)

(73) Assignee: Rohm Co., Ltd., Kyoto-shi, Kyoto (JP)

(21) Appl. No.: 16/317,852

(22) PCT Filed: Jul. 11, 2017
(86) PCT No.: PCT/JP2017/025314

§ 371 Date: Jan. 15, 2019

(30) Foreign Application Priority Data
Jul. 15, 2016 (JP) 2016-140878

(51) Int. Cl. H01L 29/739; H01L 21/02; H01L 21/04; H01L 29/66; H01L 29/10; H01L 29/78; H01L 21/8249

(52) U.S. Cl. CPC H01L 29/7395; H01L 21/02529; H01L 21/046; H01L 21/8249; H01L 29/1095; H01L 29/66712; H01L 29/7805; H01L 29/66333

(57) ABSTRACT

A semiconductor device includes a first conductivity type first semiconductor layer, a second conductivity type second semiconductor layer on the first semiconductor layer, an MIS transistor structure defined in a surface portion of the second semiconductor layer, a trench defined selectively in the first semiconductor layer, and a first electrode defined on a back surface of the first semiconductor layer such that the first electrode enters the trench, in which the second semiconductor layer has a second conductivity type region in a manner extending across a first portion exposed at the bottom portion of the trench and a second portion in contact with the first conductivity type layer, and the first electrode is in Ohmic contact with the second conductivity type region at least at the bottom portion of the trench and in Ohmic contact with the first semiconductor layer, and the second conductivity type region has a carrier lifetime of equal to or longer than 0.1 μs.

### CROSS-REFERENCE TO RELATED APPLICATIONS

This application is a U.S. National Phase application submitted under 35 U.S.C. § 371 of Patent Cooperation Treaty application serial no. PCT/JP2017/025314, filed Jul. 11, 2017, and entitled SEMICONDUCTOR DEVICE AND METHOD FOR MANUFACTURING SEMICONDUCTOR DEVICE, which application claims priority to Japanese patent application serial no. JP 2016-140878, filed Jul. 15, 2016, and entitled

[symbol]

[symbol]

Patent Cooperation Treaty application serial no. PCT/JP2017/025314, published as WO 2018/012510, and Japanese patent application serial no. JP 2016-140878, are incorporated herein by reference.

### TECHNICAL FIELD

The present invention relates to a semiconductor device and a method for manufacturing the same.

### BACKGROUND

There has recently been proposed a so-called hybrid MOSFET in which a p-type collector region is provided selectively on a back surface of a vertical n-channel MOSFET to include not only a MOSFET feature but also an IGBT feature to thereby achieve satisfactory switching characteristics in both the low-current region and the high-current region. Hybrid MOSFETs of this type are disclosed in, for example, Patent Literatures 1 and 2.

### CITATION LIST

### Patent Literatures

Patent Literature 1: Japanese Translation of International Application (Kohyo) No. 2008-537359

Patent Literature 2: WO2015/159953

### SUMMARY OF INVENTION

### Technical Problem

In Patent Literatures 1 and 2, at least a p-type collector region is formed through ion implantation. Many crystal defects may be formed in semiconductor layers through ion implantation and have an influence on the bipolar operation (IGBT mode) of the device. For example, in an SiC semiconductor layer, ion implantation may cause carbon (C) holes and/or silicon (Si) holes to be generated in the SiC semiconductor layer, resulting in a reduction in the minority carrier lifetime. As a result, the effect of conductivity modulation may be reduced in the IGBT mode to cause an increase in the ON-resistance and the ON-voltage.

It is hence an object of the present invention to provide a semiconductor device capable of achieving satisfactory switching characteristics in both the low-current region and the high-current region, in which the defect level can be made lower than ever before, and a method for manufacturing the same.

### Solution to the Problem

A semiconductor device according to a preferred embodiment of the present invention includes a first conductivity type first semiconductor layer, a second conductivity type second semiconductor layer on the first semiconductor layer, an MIS transistor structure defined in a surface portion on the side of the second semiconductor layer opposite to the first semiconductor layer, a trench defined selectively in the first semiconductor layer and having a bottom portion reaching the second semiconductor layer, and a first electrode defined on a back surface of the first semiconductor layer such that the first electrode enters the trench, in which the second semiconductor layer has a second conductivity type region in a manner extending across a first portion exposed at the bottom portion of the trench and a second portion in contact with the first conductivity type layer, and the first electrode is in Ohmic contact with the second conductivity type region at least at the bottom portion of the trench and in Ohmic contact with the first semiconductor layer, and the first semiconductor layer or the second conductivity type region has a carrier lifetime of equal to or longer than 0.1 μs. It is noted that the first electrode may be in Ohmic contact with the first semiconductor layer at least in a side portion of the trench or in a region in which the trench is not defined (e.g. on the back surface of the first semiconductor layer).

In accordance with the arrangement above, the second conductivity type region and the first semiconductor layer of the semiconductor device constitute, respectively, a drain region of a MISFET (Metal Insulator Semiconductor Field Effect Transistor) and a collector region of an IGBT (Insulated Gate Bipolar Transistor) with respect to the MIS transistor structure of the second semiconductor layer. That is, by Ohmic contact portions having respectively different conductivity types with respect to the common MIS transistor structure being provided on the back surface, the semiconductor device has a Hybrid-MIS (Hybrid-Metal Insulator Semiconductor) structure in which a MISFET and an IGBT are integrated in the same semiconductor layer.

MISFET is available as a device used mainly in the low-withstand voltage region (e.g. 5 kV or lower). When MISFET is turned ON, the drain current rises at a drain voltage of 0 V and then increases linearly with an increase in the drain voltage. MISFET can thus show satisfactory low-current region characteristics. Meanwhile, since the drain current increases linearly with respect to an increase in the drain voltage, it is necessary, when using MISFET in the high-current region, to increase the area of the semiconductor layer in response to an increase in the drain voltage applied.

On the other hand, IGBT is available as a device used mainly in the high-withstand voltage region (e.g. 10 kV or higher). In the case of IGBT, which has the conductivity modulation characteristics of a bipolar transistor, high-current control is possible at high withstand voltage. IGBT can thus show satisfactory high-current region characteristics without increasing the area of the semiconductor layer.

As above, it is possible to achieve a wide operating range from the low-withstand voltage region to the high-withstand voltage region by integrating a MISFET and an IGBT in the same semiconductor layer. That is, it is possible to provide a semiconductor device capable of achieving a MISFET (unipolar) operation in the low-current region and an IGBT (bipolar) operation in the high-current region while being used as a high-withstand voltage device. As a result, it is possible to accomplish satisfactory switching characteristics in both the low-current region and the high-current region.

A semiconductor device according to a preferred embodiment of the present invention can be manufactured by, for example, a semiconductor device manufacturing method including the steps of defining a second conductivity type second semiconductor layer on one of the surfaces of a first conductivity type first semiconductor layer, defining an MIS transistor structure in a surface portion on the side of the second semiconductor layer opposite to the first semiconductor layer, selectively etching the other surface of the first semiconductor layer opposite to the second semiconductor layer to define a trench having a bottom portion reaching the second semiconductor layer, and defining a first electrode to be in Ohmic contact with the second conductivity type region of the second semiconductor layer at least at the bottom portion of the trench and in Ohmic contact with the first semiconductor layer on the other surface of the first semiconductor layer so as to enter the trench.

In accordance with the method above, ion implantation is not required to form the first semiconductor layer. Further, since the first semiconductor layer is formed by an epitaxial method, laser annealing is not required for activation. This can reduce the generation of crystal defects in the vicinity of the interface between the first semiconductor layer and the second semiconductor layer, whereby the second conductivity type region can have a longer minority carrier lifetime in the IGBT mode. For example, if the second conductivity type region is an n-type region, holes can have a longer lifetime, while if the second conductivity type region is a p-type region, electrons can have a longer lifetime. As a result, the second conductivity type region can have a carrier lifetime of equal to or longer than 0.1 μs, like the semiconductor device according to the preferred embodiment of the present invention.

In the semiconductor device according to a preferred embodiment of the present invention, the trench may be defined to have a depth greater than a thickness of the first semiconductor layer such that a recessed portion is defined in the second semiconductor layer.

In the semiconductor device according to a preferred embodiment of the present invention, the second semiconductor layer may have a flat back surface continuing between the first portion and the second portion.

In the semiconductor device according to a preferred embodiment of the present invention, a side portion of the trench may be constituted only by the first semiconductor layer.

In the semiconductor device according to a preferred embodiment of the present invention, the MIS transistor structure may include a first conductivity type body region, a second conductivity type source region defined in a surface portion of the body region, a gate insulating film defined being contact with the body region, and a gate electrode opposed to the body region with the gate insulating film therebetween, and the second conductivity type region may include a drift region defined nearer the first semiconductor layer with respect to the body region and in contact with the body region.

The semiconductor device according to a preferred embodiment of the present invention may further include a surface terminal structure defined in an outer peripheral region around an active region in which the MIS transistor structure is defined.

In the semiconductor device according to a preferred embodiment of the present invention, the second conductivity type region may further include a field stop region defined between the drift region and the first semiconductor layer and having a concentration higher than that of the drift region.

In accordance with the arrangement above, upon voltage resistance of the semiconductor device (when a high bias is applied between the drain and the source of the semiconductor device), it is possible to prevent a depletion layer extending from the MIS transistor structure on the low-voltage side from reaching the first semiconductor layer on the high-voltage side. This can prevent leak current due to a punch-through phenomenon. Also, having a concentration higher than in the drift region can reduce the contact resistance against the first electrode.

In the semiconductor device according to a preferred embodiment of the present invention, the trench may section the first semiconductor layer into multiple first conductivity type units having at least a minimum width Wmin, and the width Wmin of the first conductivity type units may be equal to or greater than the width of one cell in the MIS transistor structure or equal to or greater than twice the thickness of the second semiconductor layer.

In the semiconductor device according to a preferred embodiment of the present invention, the trench may section the first semiconductor layer into multiple first conductivity type units, and the multiple first conductivity type units may be arranged in a striped manner in plan view.

In the semiconductor device according to a preferred embodiment of the present invention, the trench may section the first semiconductor layer into multiple first conductivity type units, and the multiple first conductivity type units may be each defined in a polygonal shape and arranged discretely in plan view.

In the semiconductor device according to a preferred embodiment of the present invention, the trench may section the first semiconductor layer into multiple first conductivity type units, and the multiple first conductivity type units may be each defined in a circular shape and arranged discretely in plan view.

In the semiconductor device according to a preferred embodiment of the present invention, the first electrode may be defined in a manner following the back surface of the first semiconductor layer and an interior surface of the trench.

In the semiconductor device according to a preferred embodiment of the present invention, the first electrode may be buried in the trench and further defined on the back surface of the first semiconductor layer.

In the semiconductor device according to a preferred embodiment of the present invention, the first semiconductor layer may have a thickness of 5 μm to 350 μm.

The semiconductor device according to a preferred embodiment of the present invention may further include a second electrode defined on the second semiconductor layer and connected electrically to the MIS transistor structure.

In the semiconductor device according to a preferred embodiment of the present invention, the first semiconductor layer and the second semiconductor layer may be made of a wide bandgap semiconductor.

In the semiconductor device manufacturing method according to a preferred embodiment of the present invention, the step of defining the second semiconductor layer may include the step of epitaxially growing the second semiconductor layer on the first semiconductor layer that is prepared as a substrate.

In the semiconductor device manufacturing method according to a preferred embodiment of the present invention, the step of defining the second semiconductor layer may include the steps of epitaxially growing the first semiconductor layer on a second conductivity type substrate, epitaxially growing the second semiconductor layer on the first semiconductor layer, and removing the second conductivity type substrate.

The semiconductor device manufacturing method according to a preferred embodiment of the present invention may further include the step of thinning the first semiconductor layer from the other surface before the step of defining the trench.

In accordance with the method above, it is possible to reduce the time for etching the trench and thereby to improve the manufacturing efficiency.

In the semiconductor device manufacturing method according to a preferred embodiment of the present invention, the step of thinning the first semiconductor layer may include the step of polishing and finishing the other surface of the first semiconductor layer.

In accordance with the method above, it is possible to smoothen the other surface of the first semiconductor layer and thereby to bring the first electrode into satisfactory Ohmic contact with the other surface.

In the semiconductor device manufacturing method according to a preferred embodiment of the present invention, the step of defining the first electrode may include the step of laser-annealing and sintering the first electrode defined on the other surface of the first semiconductor layer.

A semiconductor device according to another preferred embodiment of the present invention also includes a first conductivity type first semiconductor layer formed by epitaxial growth, a second conductivity type second semiconductor layer defined on the first semiconductor layer formed by epitaxial growth, an MIS transistor structure defined in a surface portion on the side of the second semiconductor layer opposite to the first semiconductor layer, a trench defined selectively in the first semiconductor layer and having a bottom portion reaching the second semiconductor layer, and a first electrode defined on a back surface of the first semiconductor layer such that the first electrode enters the trench, in which the second semiconductor layer has a second conductivity type region in a manner extending across a first portion exposed at the bottom portion of the trench and a second portion in contact with the first conductivity type layer, and the first electrode is in Ohmic contact with the second conductivity type region at least at the bottom portion of the trench and in Ohmic contact with the first semiconductor layer..

### BRIEF DESCRIPTION OF THE DRAWINGS

FIG. 1 is a schematic plan view of a semiconductor device according to a preferred embodiment of the present invention.

FIG. 2 is a schematic bottom view of a semiconductor device according to a preferred embodiment of the present invention.

FIG. 3 is a cross-sectional view of the semiconductor device taken along line in FIG. 1.

FIG. 4 is a cross-sectional view of the semiconductor device taken along line IV-IV in FIG. 1.

FIGS. 5A to 5C show arrangement patterns of p⁺-type semiconductor units.

FIG. 6 is a schematic cross-sectional view of the semiconductor device in another form.

FIG. 7A shows a part of a process for manufacturing the semiconductor device of FIGS. 1 to 4.

FIG. 7B shows a step following FIG. 7A.

FIG. 7C shows a step following FIG. 7B.

FIG. 7D shows a step following FIG. 7C.

FIG. 8A shows a process for manufacturing the semiconductor device of FIGS. 1 to 4 in another form.

FIG. 8B shows a step following FIG. 8A.

FIG. 8C shows a step following FIG. 8B.

FIG. 9 is a schematic cross-sectional view of the semiconductor device in another form.

FIG. 10A shows a part of a process for manufacturing the semiconductor device of FIG. 9.

FIG. 10B shows a step following FIG. 10A.

FIG. 10C shows a step following FIG. 10B.

FIG. 11 is a schematic cross-sectional view of the semiconductor device in another form.

FIG. 12 is a schematic cross-sectional view of the semiconductor device in still another form.

FIG. 13 is a schematic cross-sectional view of the semiconductor device in a still a further form.

FIG. 14 is an inverter circuit diagram in which the semiconductor device is incorporated.

### DETAILED DESCRIPTION

Preferred embodiments of the present invention will hereinafter be described in detail with reference to the accompanying drawings.

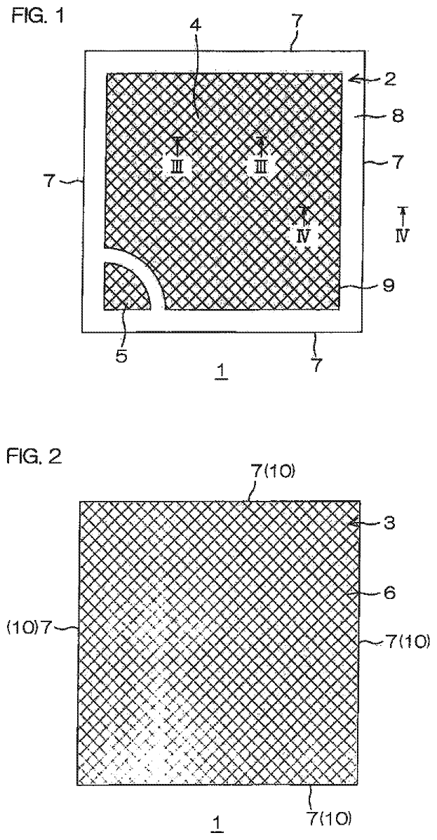

FIGS. 1 and 2 are, respectively, a plan view, and a bottom view of a semiconductor device 1 according to a preferred embodiment of the present invention.

The semiconductor device 1 has a source electrode 4 as an example of a second electrode of the present invention and a gate pad 5 on a surface 2, and has a drain electrode 6 as an example of a first electrode of the present invention on a back surface 3.

The source electrode 4 is defined in an approximately quadrilateral shape almost over the entire area of the surface 2 and has a peripheral edge 9 at a position inward away from an end face 7 of the semiconductor device 1. The peripheral edge 9 is provided with a surface terminal structure such as a guard ring as will be described hereinafter. This causes a semiconductor region 8 to be exposed around the source electrode 4 at the surface 2 of the semiconductor device 1. In this preferred embodiment, the semiconductor region 8 surrounding the source electrode 4 is exposed. The gate pad 5 is provided at one of the corners of the source electrode 4 in a manner spaced from the source electrode 4 to be connected to a gate electrode 26 of each MIS transistor structure 22 to be described hereinafter.

The drain electrode 6 is defined in a quadrilateral shape over the entire area of the back surface 3 and has a peripheral edge 10 coinciding with (continuing to) the end face 7 of the semiconductor device 1. It is noted that a trench 14 is defined in the back surface 3 as will be described hereinafter, though not shown in FIG. 2.

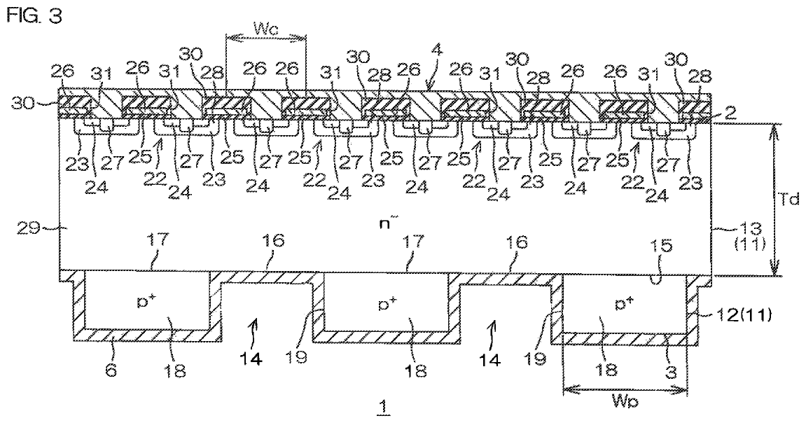

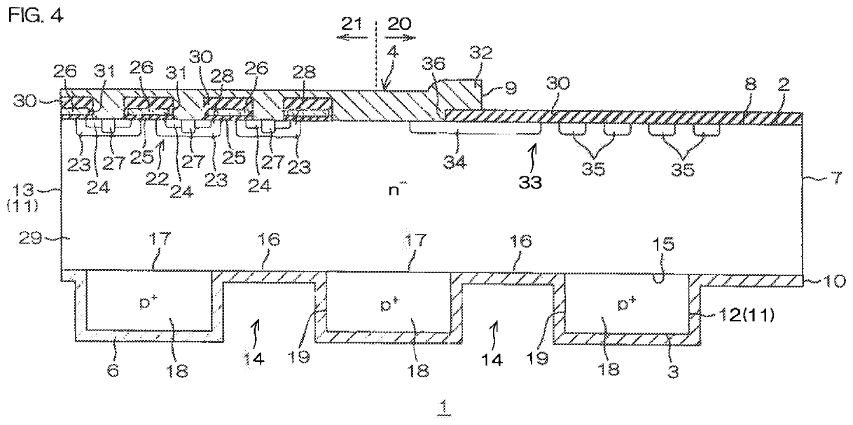

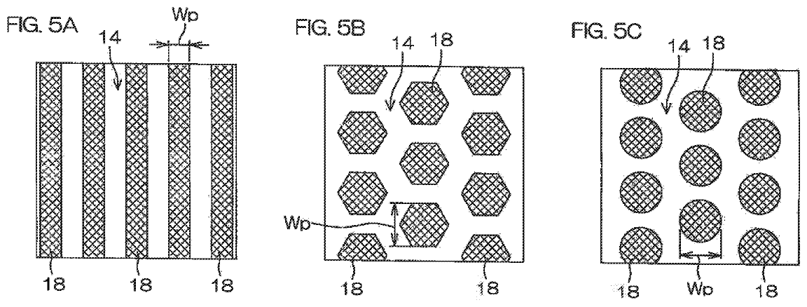

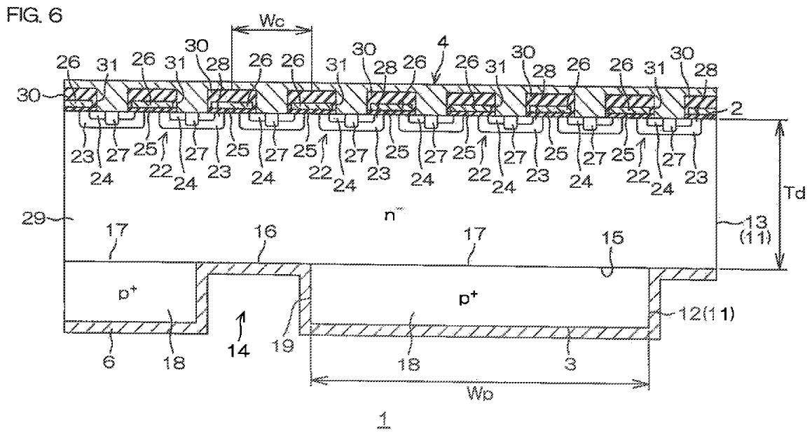

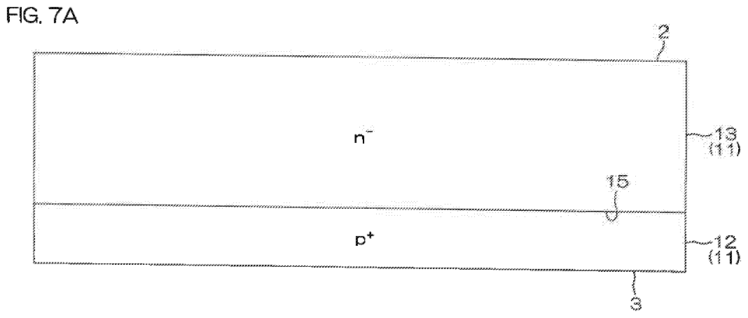

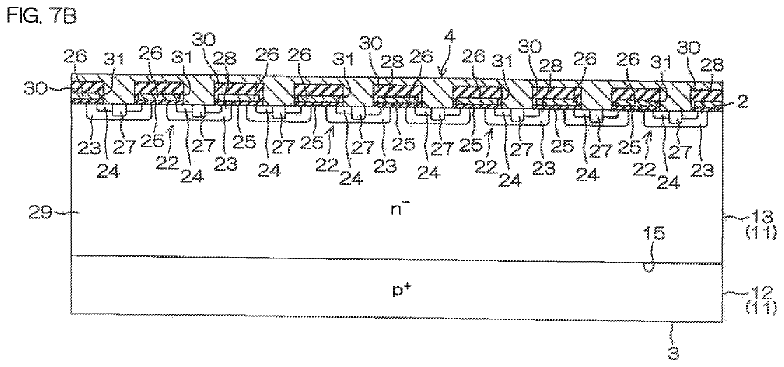

FIGS. 3 and 4 are cross-sectional views of the semiconductor device 1 taken, respectively, along line III-III and line IV-IV in FIG. 1. FIGS. 5A to 5C show arrangement patterns of p⁺-type semiconductor units 18 when viewed on the back surface. FIG. 6 also shows the semiconductor device 1 in another form, in which the sizes of the p⁺-type semiconductor units 18 are different.

The semiconductor device 1 includes a semiconductor layer 11 made of SiC. The semiconductor layer 11 has a surface 2 as an Si plane of SiC and, opposite thereto, a back surface 3 as a C plane of SiC, as well as an end face 7 extending in a direction intersecting with the surface 2 (extending in the vertical direction in FIG. 4). The surface 2 may not be an Si plane of SiC and the back surface 3 may not be a C plane of SiC.

The semiconductor layer 11 includes a p⁺-type substrate 12 as an example of a first semiconductor layer of the present invention and an n-type epitaxial layer 13 as an example of a second semiconductor layer of the present invention on the p⁺-type substrate 12.

The p⁺-type substrate 12 has a thickness of, for example, 100 μm to 400 μm. The p⁺-type substrate 12 also has an impurity concentration of, for example, 1×10¹⁷ cm⁻³ to 5×10¹⁹ cm⁻³.

The p⁺-type substrate 12 is formed selectively with trenches 14. As shown in FIGS. 3 and 4, the trenches 14 are defined almost over the entire p⁺-type substrate 12 (i.e. in both an active region 21 and an outer peripheral region 20 to be described hereinafter).

Each trench 14 reaches the n-type epitaxial layer 13 from the back surface of the p⁺-type substrate 12 (the back surface 3 of the semiconductor layer 11). In this preferred embodiment, the depth position of the bottom portion of each trench 14 is at the same level as a back surface 15 of the n-type epitaxial layer 13 (the interface between the p⁺-type substrate 12 and the n-type epitaxial layer 13). In this preferred embodiment, a side portion (side surface 19) of each trench 14 is formed perpendicularly to the bottom portion of the trench 14 (the back surface 15 of the n-type epitaxial layer 13).

The trenches 14 also section the p⁺-type substrate 12 into multiple p⁺-type semiconductor units 18. The p⁺-type semiconductor units 18 are p⁺-type semiconductor portions divided by the trenches 14 that reach the n-type epitaxial layer 13 and separated physically and electrically from each other in the horizontal direction. The p⁺-type semiconductor units 18 can be defined in various patterns by patterning the trenches 14. For example, the multiple p⁺-type semiconductor units 18 may be arranged in a striped manner in plan view (bottom view) as indicated by hatching in FIG. 5A. The multiple p⁺-type semiconductor units 18 may alternatively be each defined in a polygonal shape (in a regular hexagonal shape in FIG. 5B) and arranged discretely in plan view as indicated by hatching in FIG. 5B. In FIG. 5B, the multiple p⁺-type semiconductor units 18 are arranged in a staggered manner, but may be arranged in a matrix manner. The multiple p⁺-type semiconductor units 18 may alternatively be each defined in a circular shape (in a regular circular shape in FIG. 5C) and arranged discretely in plan view as indicated by hatching in FIG. 5C. Obviously, the arrangement pattern in FIG. 5C may also be a matrix manner as is the case in FIG. 5B. It is noted that the multiple p⁺-type semiconductor units 18 uniformly have the same shape in FIGS. 5A to 5C, but may have their respective different shapes and sizes.

The n-type epitaxial layer 13 has a thickness of 5 μm to 250 μm depending on a desired voltage resistance. The n-type epitaxial layer 13 also has an impurity concentration of 1×10^{–}cm⁻³ to 1×10¹⁷ cm⁻³. The n-type epitaxial layer 13 includes an outer peripheral region 20 set in its peripheral edge portion (in the vicinity of the end face 7) and an active region 21 surrounded by the outer peripheral region 20.

In the active region 21, multiple MIS transistor structures 22 are defined in a surface portion of the n-type epitaxial layer 13. The MIS transistor structures 22 each include a p-type body region 23, an n⁺-type source region 24, a gate insulating film 25, a gate electrode 26, and a p⁺-type body contact region 27.

More specifically, multiple p-type body regions 23 are defined in a surface portion of the n-type epitaxial layer 13. Each p-type body region 23 defines a minimum unit (unit cell) in the active region 21 through which a current flows. The n⁺-type source region 24 is defined in an interior region of each p-type body region 23 in a manner exposed at the surface 2 of the n-type epitaxial layer 13. In each p-type body region 23, the region outside the n⁺-type source region 24 (the region surrounding the n⁺-type source region 24) defines a channel region 28. The gate electrode 26 extends across adjoining unit cells and is opposed to the channel region 28 with the gate insulating film 25 therebetween. The p⁺-type body contact region 27 penetrates through the n⁺-type source region 24 to connect electrically to the p-type body region 23.

The parts of each MIS transistor structure 22 will additionally be described. The p-type body region 23 has an impurity concentration of, for example, 1×10¹⁶ cm⁻³ to 1×10¹⁹ cm⁻³, the n⁺-type source region 24 has an impurity concentration of, for example, 1×10¹⁹ cm⁻³ to 1×10²¹ cm⁻³, and the p⁺-type body contact region 27 has an impurity concentration of, for example, 1×10¹⁹ cm⁻³ to 1×10²¹ cm⁻³. The gate insulating film 25 is made of, for example, silicon oxide (SiO₂) and has a thickness of 20 nm to 100 nm. The gate electrode 26 is made of, for example, polysilicon.

Also, in FIG. 3, provided that the distance between the gate electrodes 26 of adjoining MIS transistor structures 22 is the cell width Wc of each MIS transistor structure 22, the width Wp of each p⁺-type semiconductor unit 18 in FIGS. 5A to 5C is preferably equal to or greater than the cell width Wc. Alternatively, as shown in FIG. 6, provided that the thickness of the n-type epitaxial layer 13 is Td, the width Wp of each p⁺-type semiconductor unit 18 may be equal to or greater than twice the thickness Td. This allows holes to be injected efficiently from each p⁺-type semiconductor unit 18, whereby even a low drain voltage can allow for transition to the IGBT mode. It is noted that the width Wp is only required to be measured at the narrowest portion of each p⁺-type semiconductor unit 18, as shown in FIGS. 5A to 5C.

The n⁻-type region of the n-type epitaxial layer 13 nearer the back surface 15 than the MIS transistor structures 22 is an n⁻-type drift region 29 as an example of a second conductivity type region of the present invention and exposed at the back surface 15 of the n-type epitaxial layer 13. That is, the n⁻-type drift region 29 extends across a first portion 16 and a second portion 17 in the n-type epitaxial layer 13 to form a contact portion with the bottom portions of the trenches 14 and the p⁺-type substrate 12.

On the surface of the semiconductor layer 11, an interlayer insulating film 30 is defined extending across the active region 21 and the outer peripheral region 20. The interlayer insulating film 30 is made of, for example, silicon oxide (SiO₂) and has a thickness of 0.5 μm to 3.0 μm. The interlayer insulating film 30 is formed with contact holes 31 through which the n⁺-type source region 24 and the p⁺-type body contact region 27 are exposed in each unit cell.

The source electrode 4 is defined on the interlayer insulating film 30. The source electrode 4 enters the contact holes 31 to be in Ohmic contact with the n⁺-type source region 24 and the p⁺-type body contact region 27. The source electrode 4 extends from the active region 21 to the outer peripheral region 20 and has an overlap portion 32 overlapping the interlayer insulating film 30 in the outer peripheral region 20.

As shown in FIG. 4, a surface terminal structure 33 is defined in a surface portion of the n-type epitaxial layer 13 in the outer peripheral region 20. The surface terminal structure 33 may consist of multiple portions including at least one portion overlapping a peripheral edge portion of the source electrode 4 (a peripheral edge portion of a joint portion with the n-type epitaxial layer 13). In FIG. 4, it includes an innermost RESURF (Reduced Surface Field) layer 34 and multiple guard ring layers 35 surrounding the RESURF layer 34. The RESURF layer 34 is defined in a manner extending across the inside and the outside of an opening 36 of the interlayer insulating film 30 and in contact with the peripheral edge portion of the source electrode 4 within the opening 36. The multiple guard ring layers 35 are defined in a manner spaced from each other. The RESURF layer 34 and the guard ring layers 35 are defined by p-type impurity regions, but may be made of a high-resistance region. In the case of the high-resistance region, the RESURF layer 34 and the guard ring layers 35 may have a crystal defect concentration of 1×10¹⁴ cm⁻³ to 1×10²¹ cm⁻³.

The drain electrode 6 is defined on the back surface 3 of the p⁺-type substrate 12. The drain electrode 6 is defined in a manner following the back surface 3 of the p⁺-type substrate 12 and the interior surface of each trench 14. As a result, the distance between one of the surfaces of the drain electrode 6 in contact with the back surface 3 of the p⁺-type substrate 12 and the interior surface of each trench 14 and the other opposite surface (the thickness of the drain electrode 6) is constant. The drain electrode 6 is in Ohmic contact with the n⁻-type drift region 29 at the bottom portion of each trench 14 (at the back surface 15) and in Ohmic contact with the p⁺-type substrate 12 at the side portion (side surface 19) of each trench 14 and the back surface 3 of the p⁺-type substrate 12. The drain electrode 6 is shared by the multiple unit cells. The drain electrode 6 is also made of a metal (e.g. Ti, Ni) with which Ohmic contact can be made with the n⁻-type drift region 29 and the p⁺-type substrate 12.

In the semiconductor device 1, the n⁻-type (i.e. n-type) drift region 29 and the p⁺-type (i.e. p-type) substrate 12 are exposed on the back surface 3 of the semiconductor layer 11, with both of which the drain electrode 6 is in Ohmic contact as a common electrode. Accordingly, the n⁻-type drift region 29 and the p⁺-type substrate 12 constitute, respectively, a drain region of a MISFET (Metal Insulator Semiconductor Field Effect Transistor) and a collector region of an IGBT (Insulated Gate Bipolar Transistor) with respect to each MIS transistor structure 22. That is, by Ohmic contact portions having respectively different conductivity types with respect to the common MIS transistor structure 22 being provided on the back surface, the semiconductor device 1 has a Hybrid-MIS (Hybrid-Metal Insulator Semiconductor) structure in which a MISFET and an IGBT are integrated in the same semiconductor layer.

MISFET is available as a device used mainly in the low-withstand voltage region (e.g. 5 kV or lower). In the semiconductor device 1, the MISFET is therefore first turned ON when a voltage is applied between the source and the drain and a voltage equal to or higher than a threshold voltage is applied to the gate electrode 26. The source electrode 4 and the drain electrode 6 are made electrically conductive via the first portion 16 of the n-type epitaxial layer 13 (MISFET mode). For example, the drain current rises at a source-drain voltage of 0 V and then increases linearly with an increase in the drain voltage until a pinch-off occurs. MISFET can thus show satisfactory low-current region characteristics. Meanwhile, since the drain voltage increases with respect to an increase in the drain current, using MISFET in the high-current region results in an increase in the conducting loss of MISFET, which is determined by a product between the drain voltage and the drain current. It is noted that increasing the area of the semiconductor layer can require only a reduced drain voltage for a high current to flow and, as a result, reduce the conducting loss of MISFET, though the manufacturing cost increases significantly.

On the other hand, IGBT is available as a device used mainly in the high-withstand voltage region (e.g. 10 kV or higher). In the semiconductor device 1, after the source and the drain are made electrically conductive in the MISFET mode, when the voltage between the source and the drain becomes equal to or higher than the rising voltage of a parasitic diode (pn diode) constituted by the pn junction between the p-type body region 23 and the n⁻-type drift region 29, transition to the high-current region occurs. In the high-current region, electrons flow into the n⁻-type drift region 29. The electrons act as a base current of the pnp transistor constituted by the p-type body region 23, the n⁻-type drift region 29, and the p⁺-type substrate 12 (collector region), and the pnp transistor is made electrically conductive. Since electrons are fed from the n⁺-type source region 24 (emitter region) and holes are injected from the p⁺-type substrate 12, electrons and holes are accumulated excessively in the n⁻-type drift region 29. This causes a conductivity modulation in the n⁻-type drift region 29, whereby the n⁻-type drift region 29 undergoes transition to a high-conductivity state and the IGBT is turned ON. That is, the source electrode 4 and the drain electrode 6 are made electrically conductive via the second portion 17 of the n-type epitaxial layer 13 (IGBT mode). In the case of IGBT, which thus has the conductivity modulation characteristics of a bipolar transistor, high-current control is possible at high withstand voltage. IGBT can thus show satisfactory high-current region characteristics without increasing the area of the semiconductor layer compared to MISFET.

As above, it is possible to achieve a wide operating range from the low-withstand voltage region to the high-withstand voltage region by integrating a MISFET and an IGBT in the same semiconductor layer. That is, it is possible to provide a semiconductor device capable of achieving a MISFET (unipolar) operation in the low-current region and an IGBT (bipolar) operation in the high-current region while being used as a high-withstand voltage device. As a result, the semiconductor device 1 can accomplish satisfactory switching characteristics in both the low-current region and the high-current region.

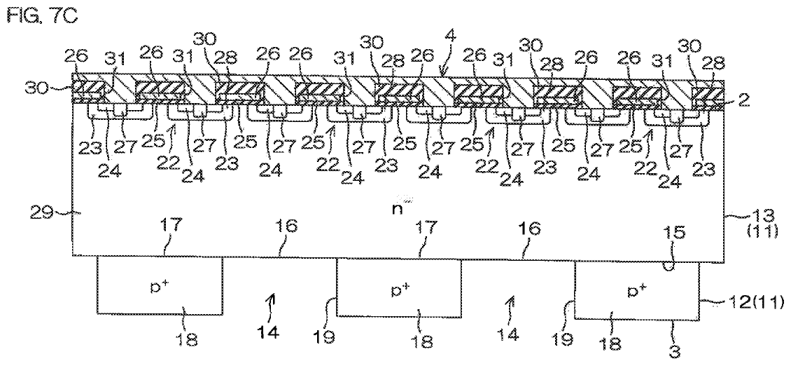

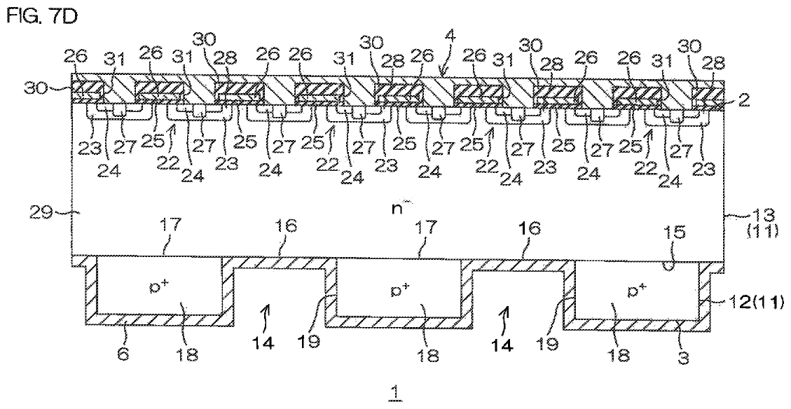

Next will be described a method for manufacturing the semiconductor device 1 with reference to FIGS. 7A to 7D.

FIGS. 7A to 7D show a sequence of steps of a process for manufacturing the semiconductor device 1 in FIGS. 1 to 4. It is noted that in FIGS. 7A to 7D, only a cross-sectional portion of the semiconductor device 1 is shown correspondingly to FIG. 3.

To manufacture the semiconductor device 1, an n-type epitaxial layer 13 is first grown epitaxially on a p⁺-type substrate 12 in a wafer state, as shown in FIG. 7A.

Next, as shown in FIG. 7B, such MIS transistor structures 22 as mentioned above are formed in a surface portion of the n-type epitaxial layer 13. In this case, a surface terminal structure 33 can be formed through reduced steps if it is formed in an ion implantation step when p-type body regions 23 of the MIS transistor structures 22 are formed (not shown), but may be formed in a separate step. An interlayer insulating film 30 (not shown) and a source electrode 4 are then formed.

Next, as shown in FIG. 7C, the p⁺-type substrate 12 is selectively etched on the back surface 3 to form trenches 14 reaching the n-type epitaxial layer 13 (n⁻-type drift region 29).

It is noted that before the trenches 14 are formed, the step of thinning the p⁺-type substrate 12 may be performed. Thus thinning in advance allows to reduce the time for etching and thereby to improve the manufacturing efficiency. In this step of thinning, the p⁺-type substrate 12 may be thinned by, for example, grinding (e.g. ground by about 50 μm to 300 μm) on the back surface 3 and then finished with polishing (e.g. CMP). In the step of polishing, the p⁺-type substrate 12, if remaining after the grinding, may be further thinned. Thus finally performing the step of polishing allows the p⁺-type substrate 12 exposed at the back surface 3 to have a smoothened surface state, with which a drain electrode 6 can come into satisfactory Ohmic contact.

Next, as shown in FIG. 7D, a metal film (e.g. Ti/Al) is formed by, for example, a sputtering method over the entire back surface 3 of the p⁺-type substrate 12. The metal film is deposited not only on the back surface 3 of the p⁺-type substrate 12, but also on the interior surface of each trench 14 (on the back surface 15 of the n-type epitaxial layer 13 and on the side surface 19 of each trench 14). This causes the drain electrode 6 to be formed. After the formation of the drain electrode 6, the drain electrode 6 may be laser-annealed and sintered.

The semiconductor layer 11 is then cut along dicing lines set at predefined positions. This provides individualized semiconductor devices 1.

In accordance with the method above, since the p⁺-type substrate 12 is used for Ohmic contact with the drain electrode 6 in each semiconductor device 1, no ion implantation is required into the n⁻-type drift region 29 of the n-type epitaxial layer 13 to define a p⁺-type region. This can reduce the generation of crystal defects in the vicinity of the pn junction between the p⁺-type substrate 12 and the n⁻-type drift region 29, whereby the n⁻-type drift region 29 can have a longer minority carrier (i.e. hole) lifetime in the IGBT mode of each semiconductor device 1. As a result, the n⁻-type drift region 29 can have a carrier lifetime of equal to or longer than 0.1 μs.

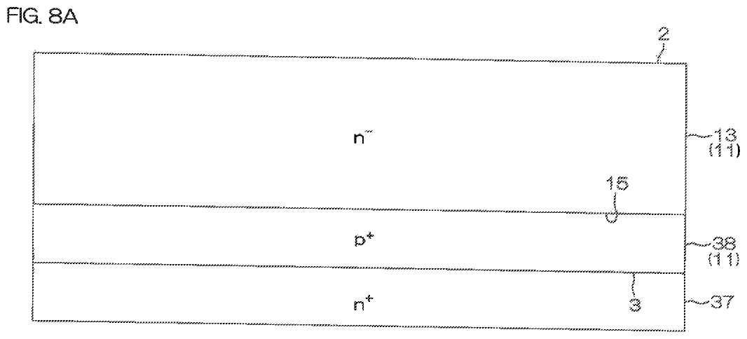

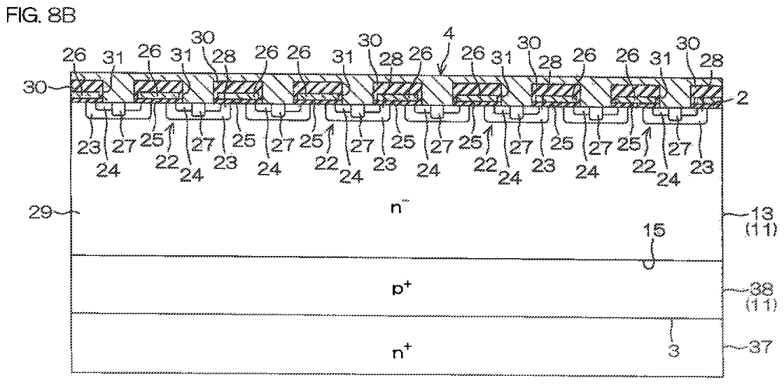

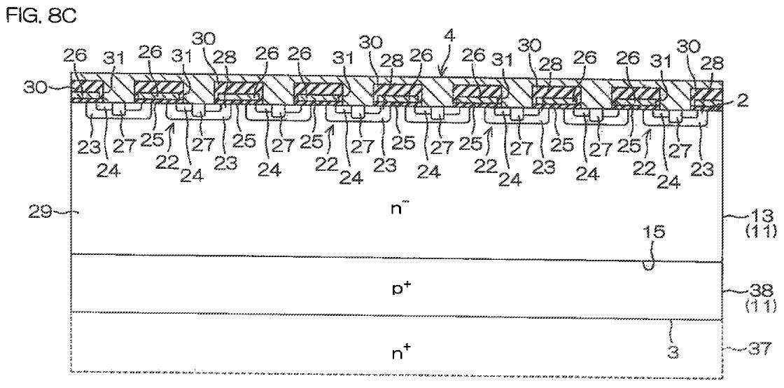

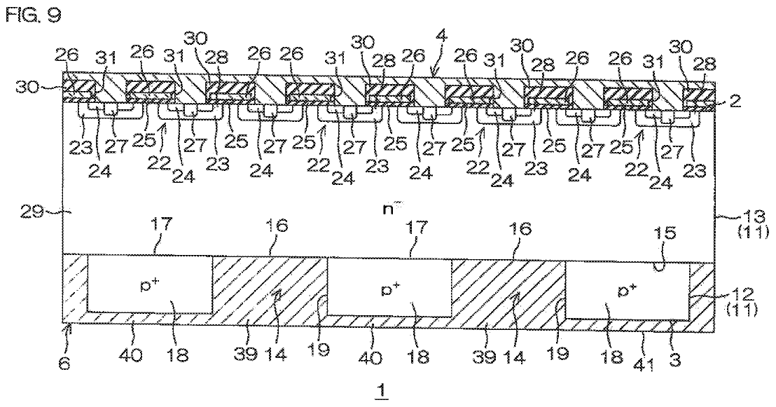

It is noted that while the p⁺-type substrate 12 is prepared, on which the n-type epitaxial layer 13 is grown in the step of FIG. 7A, the steps of FIGS. 8A to 8C may, for example, be performed instead of the steps of FIGS. 7A and 7B because p-type substrates are expensive relative to n-type substrates.

Specifically, as shown in FIG. 8A, an n⁺-type substrate 37 in a wafer state is first prepared, and then a p⁺-type epitaxial layer 38 and an n-type epitaxial layer 13 are epitaxially grown on the n⁺-type substrate 37 instead of the p⁺-type substrate 12.

Next, as shown in FIG. 8B, such MIS transistor structures 22 as mentioned above are formed in a surface portion of the n-type epitaxial layer 13 with the n⁺-type substrate 37 remaining.

Next, as shown in FIG. 8C, the n⁺-type substrate 37 is removed to expose the entire back surface 3 of the p⁺-type epitaxial layer 38. In this step, the n⁺-type substrate 37 may be almost entirely removed by, for example, grinding on the back surface of the n⁺-type substrate 37 and then finished with polishing (e.g. CMP).

Thereafter, it is only required to perform the steps shown in FIGS. 7C and 7D on the layered structure of the p⁺-type epitaxial layer 38 and the n-type epitaxial layer 13.

Employing the steps of FIGS. 8A to 8C allows to eliminate the need for using an expensive p-type substrate and thereby reduce the manufacturing cost.

FIG. 9 is a schematic cross-sectional view of the semiconductor device 1 in another form.

The drain electrode 6, which is defined in a manner following the back surface 3 of the p⁺-type substrate 12 and the interior surface of each trench 14 in FIGS. 3 and 4, may be buried in the trenches 14 and further defined on the back surface 3 of the p⁺-type substrate 12 as shown in FIG. 9. That is, the drain electrode 6 may include a relatively thick first portion 39 buried in the trenches 14 and a second portion 40 defined on the back surface 3 of the p⁺-type substrate 12 and relatively thinner than the first portion 39. This may cause the drain electrode 6 to have a flat back surface 41 continuing between a region opposed to the p⁺-type substrate 12 and a region opposed to the trenches 14.

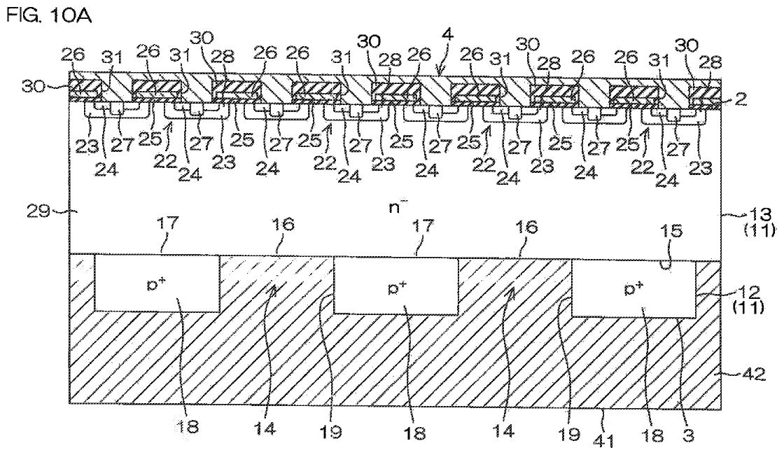

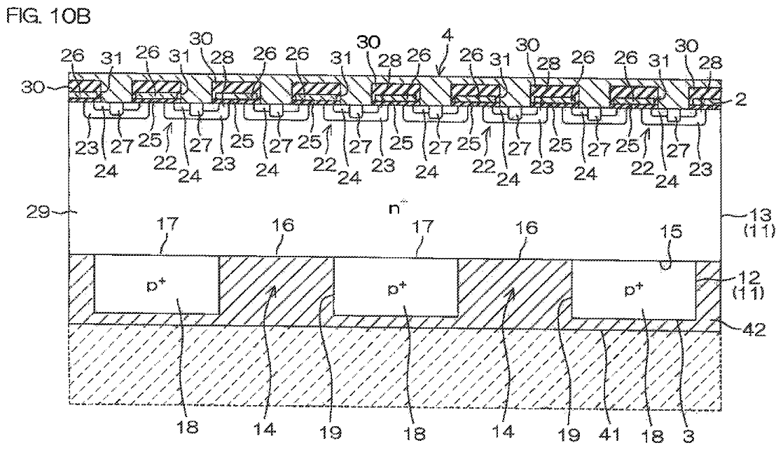

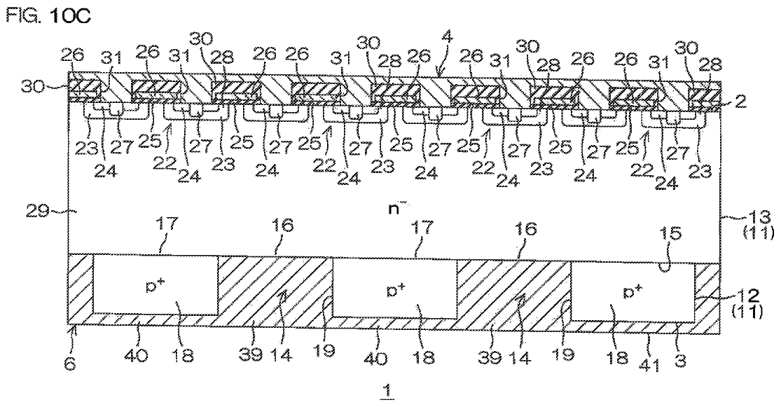

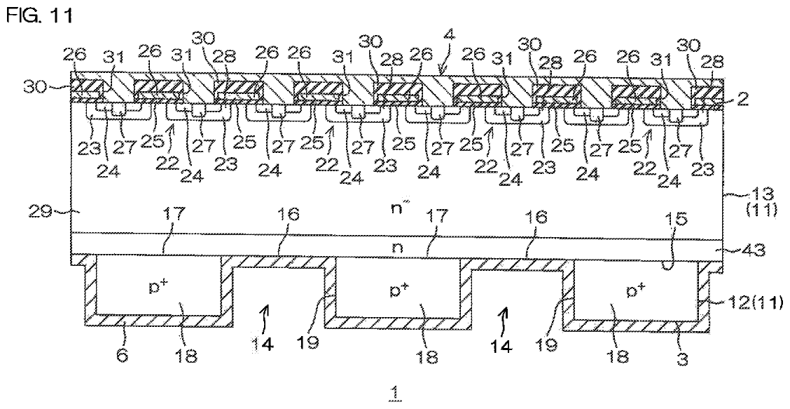

The structure shown in FIG. 9 can be obtained by, for example, performing the steps of FIGS. 10A to 10C instead of the step of FIG. 7D.

Specifically, as shown in FIG. 10A, a metal film 42 (e.g. Ti/Al) is first formed by, for example, a sputtering method over the entire back surface 3 of the p⁺-type substrate 12. The metal film 42 is deposited continuously until the trenches 14 are filled up with the metal film 42 and the back surface 3 of the p⁺-type substrate 12 is covered entirely.

Next, as shown in FIG. 10B, the step of thinning the metal film 42 is performed. In this step of thinning, the metal film 42 may be thinned by, for example, grinding on the back surface 41 and then finished with polishing (e.g. CMP). In the step of polishing, the metal film 42, if remaining after the grinding, may be further thinned.

This provides a drain electrode 6 buried in the trenches 14 and further defined on the back surface 3 of the p⁺-type substrate 12, as shown in FIG. 10C.

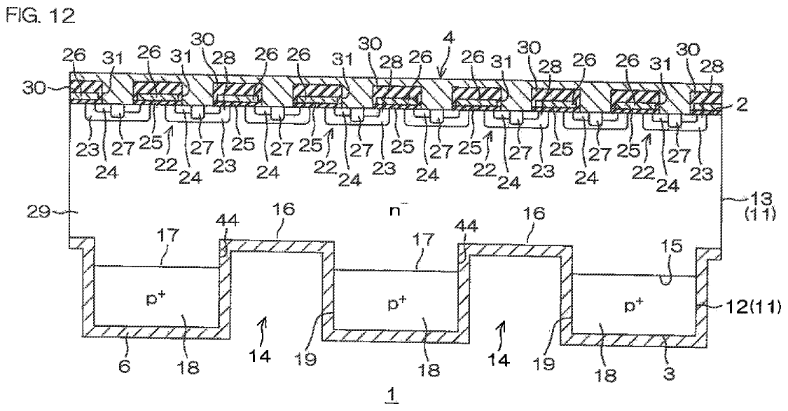

FIG. 11 is a schematic cross-sectional view of the semiconductor device 1 in another form.

As shown in FIG. 11, the semiconductor device 1 may further include an n-type field stop region 43 having a concentration higher than that of the n⁻-type drift region 29 between the n⁻-type drift region 29 and the p⁺-type substrate 12. With the n-type field stop region 43 thus defined, when a high voltage is applied between the drain and the source, it is possible to prevent a depletion layer extending from the low-voltage side (e.g. MIS transistor structures 22) from reaching the p⁺-type substrate 12 on the high-voltage side. This can prevent leak current due to a punch-through phenomenon. Also, having a concentration higher than in the n⁻-type drift region 29 can reduce the contact resistance against the drain electrode 6.

The n-type field stop region 43 may, for example, be defined over the entire back surface 15 of the n-type epitaxial layer 13 in a manner extending across the first portion 16 and the second portion 17 of the n-type epitaxial layer 13.

FIG. 12 is a schematic cross-sectional view of the semiconductor device 1 in still another form.

While the depth position of the bottom portion of each trench 14 is at the same level as the back surface 15 of the n-type epitaxial layer 13 in FIGS. 3 and 4, the trenches 14 may be defined deeper such that recessed portions 44 are defined in the n-type epitaxial layer 13, as shown in FIG. 12. This causes steps to be defined between the positions in which the trenches 14 are defined (first portion 16) and the other positions (second portion 17) in the back surface 15 of the n-type epitaxial layer 13. Also, the bottom portion of each trench 14 is formed only with the n-type epitaxial layer 13, while the side portion of each trench 14 is formed with the n-type epitaxial layer 13 and the p⁺-type substrate 12. In accordance with this arrangement, the contact area of the drain electrode 6 against the n-type epitaxial layer 13 increases and thereby the ON-resistance in the MISFET mode of the semiconductor device 1 can be reduced.

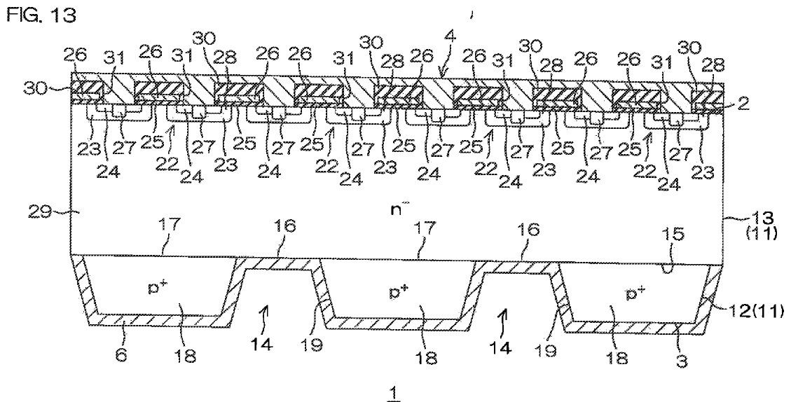

FIG. 13 is a schematic cross-sectional view of the semiconductor device 1 in still a further form.

The side portion (side surface 19) of each trench 14, which is formed perpendicularly to the bottom portion of the trench 14 (the back surface 15 of the n-type epitaxial layer 13) in FIGS. 3 and 4, may be a tapered surface inclined with respect to the bottom portion of the trench 14, as shown in FIG. 13. In accordance with this arrangement, since the side surface 19 of each trench 14 is slightly opposed to the opening end, electrode material can be deposited satisfactorily when the drain electrode 6 is formed.

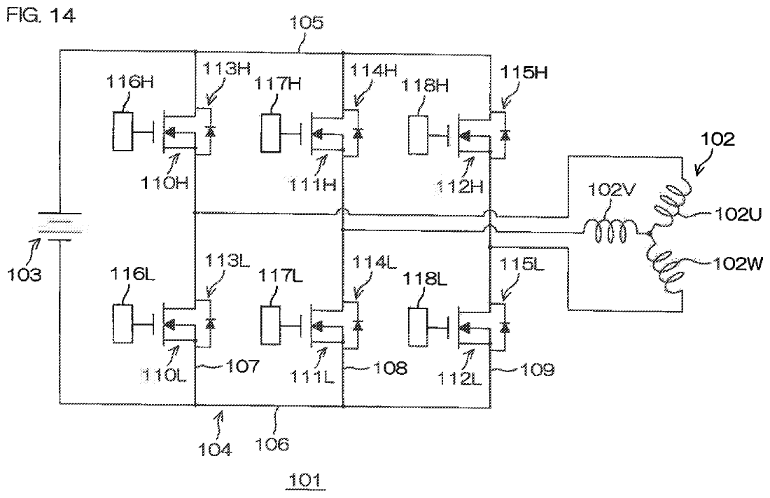

The semiconductor device 1 can then be incorporated and used in such an inverter circuit as shown in FIG. 14. FIG. 14 is an inverter circuit diagram in which multiple semiconductor devices are incorporated.

The inverter circuit 101 is a three-phase inverter circuit connected to a three-phase motor 102 serving as an example load. The inverter circuit 101 includes a DC power source 103 and a switch portion 104.

In this preferred embodiment, the DC power source 103 is at, for example, 700 V. The DC power source 103 is connected with a high-voltage wire 105 on the high-voltage side and a low-voltage wire 106 on the low-voltage side.

The switch portion 104 includes three arms 107 to 109 corresponding to the respective phases of a U-phase 102U, a V-phase 102V, and a W-phase 102W of the three-phase motor 102.

The arms 107 to 109 are connected in parallel between the high-voltage wire 105 and the low-voltage wire 106. The arms 107 to 109 include high-side transistors (semiconductor devices 1) 110H to 112H on the high-voltage side and low-side transistors (semiconductor devices 1) 110L to 112L on the low-voltage side each made of an n-channel type MISFET. Regenerative diodes 113H to 115H and 113L to 115L are connected to the respective transistors 110H to 112H and 110L to 112L in parallel in an orientation in which a forward current flows from the low-voltage side to the high-voltage side, but may be omitted by using the parasitic diodes of the respective transistors.

High-side gate drivers 116H to 118H and low-side gate drivers 116L to 118L are connected to the gates of the respective transistors 110H to 112H and 110L to 112L.

In the inverter circuit 101, an AC current can flow through the three-phase motor 102 by appropriately switching the ON/OFF control of the high-side transistors 110H to 112H and the low-side transistors 110L to 112L in the respective arms 107 to 109, that is, by appropriately switching a state where one of the transistors is switched ON and the other transistor is switched OFF in one of the arms and a state where one of the transistors is switched OFF and the other transistor is switched ON in the other arms. On the other hand, the three-phase motor 102 can be non-energized by switching OFF both the transistors in some of the arms or by switching OFF at least one of the transistors in all of the arms. The three-phase motor 102 thus performs switching operations.

While the preferred embodiment of the present invention has heretofore been described, the present invention may be practiced in other forms.

For example, the semiconductor layer 11 is not limited to a semiconductor layer made of SiC, but may be a wide bandgap semiconductor other than SiC, such as a semiconductor with a bandgap of 2 eV or larger, specifically GaN (with a bandgap of about 3.42 eV), diamond (with a bandgap of about 5.47 eV), or the like.

While the above-mentioned preferred embodiment describes only an inverter circuit for a three-phase motor as an application of the semiconductor device 1, the semiconductor device according to the present invention may be used as an inverter circuit for power source equipment or another circuit may be used in which the gate drivers in the respective transistors are grouped together.

Various other design changes may be made within the scope of the matters described in the appended claims.

This application corresponds to Japanese Patent Application No. 2016-140878 filed in the Japan Patent Office on Jul. 15, 2016, the disclosure of which is incorporated herein by reference in its entirety.

### REFERENCE SIGNS LIST

1: Semiconductor device
2: Surface
3: Back surface
4: Source electrode
6: Drain electrode
11: Semiconductor layer
12: p⁺-type substrate
13: n-type epitaxial layer
14: Trench
15: Back surface
16: First portion
17: Second portion
18: p⁺-type semiconductor unit
19: Side surface
22: MIS transistor structure
23: p-type body region
24: n⁺-type source region
25: Gate insulating film
26: Gate electrode
29: n⁻-type drift region
37: n⁺-type substrate
38: p⁺-type epitaxial layer
43: n-type field stop region

1-24. (canceled)

25. A semiconductor device comprising:
a first conductivity type first semiconductor layer;
a second conductivity type second semiconductor layer on the first semiconductor layer;
an MIS transistor structure defined in a surface portion on the side of the second semiconductor layer opposite to the first semiconductor layer;
a trench defined selectively in the first semiconductor layer and having a bottom portion reaching the second semiconductor layer; and
a first electrode defined on a back surface of the first semiconductor layer such that the first electrode enters the trench, wherein
the second semiconductor layer has a second conductivity type region in a manner extending across a first portion exposed at the bottom portion of the trench and a second portion in contact with the first conductivity type layer, and
the first electrode is in Ohmic contact with the second conductivity type region at least at the bottom portion of the trench and in Ohmic contact with the first semiconductor layer, and
the second conductivity type region has a carrier lifetime of equal to or longer than 0.1 μs.

26. The semiconductor device according to claim 25, wherein the trench is defined to have a depth greater than a thickness of the first semiconductor layer such that a recessed portion is defined in the second semiconductor layer.

27. The semiconductor device according to claim 25, wherein the second semiconductor layer has a flat back surface continuing between the first portion and the second portion.

28. The semiconductor device according to claim 25, wherein a side portion of the trench is constituted only by the first semiconductor layer.

29. The semiconductor device according to claim 25, wherein
the MIS transistor structure includes a first conductivity type body region, a second conductivity type source region defined in a surface portion of the body region, a gate insulating film being contact with the body region, and a gate electrode opposed to the body region with the gate insulating film therebetween, and wherein
the second conductivity type region includes a drift region defined nearer the first semiconductor layer with respect to the body region and in contact with the body region.

30. The semiconductor device according to claim 25, further comprising a surface terminal structure defined in an outer peripheral region around an active region in which the MIS transistor structure is defined.

31. The semiconductor device according to claim 29, wherein the second conductivity type region includes a field stop region defined between the drift region and the first semiconductor layer and having a concentration higher than that of the drift region.

32. The semiconductor device according to claim 25, wherein
the trench sections the first semiconductor layer into a plurality of first conductivity type units having at least a minimum width Wₘᵢₙ, and wherein
the width Wₘᵢₙ of the first conductivity type units is equal to or greater than the width of one cell in the MIS transistor structure.

33. The semiconductor device according to claim 25, wherein
the trench sections the first semiconductor layer into a plurality of first conductivity type units having at least a minimum width Wₘᵢₙ, and wherein
the width Wₘᵢₙ of the first conductivity type units is equal to or greater than twice a thickness of the second semiconductor layer.

34. The semiconductor device according to claim 25, wherein
the trench sections the first semiconductor layer into a plurality of first conductivity type units, and wherein
the plurality of first conductivity type units are arranged in a striped manner in plan view.

35. The semiconductor device according to claim 25, wherein
the trench sections the first semiconductor layer into a plurality of first conductivity type units, and wherein
the plurality of first conductivity type units are each defined in a polygonal shape and arranged discretely in plan view.

36. The semiconductor device according to claim 25, wherein
the trench sections the first semiconductor layer into a plurality of first conductivity type units, and wherein
the plurality of first conductivity type units are each defined in a circular shape and arranged discretely in plan view.

37. The semiconductor device according to claim 25, wherein the first electrode is defined in a manner following the back surface of the first semiconductor layer and an interior surface of the trench.

38. The semiconductor device according to claim 25, wherein the first electrode is buried in the trench and further defined on the back surface of the first semiconductor layer.

39. The semiconductor device according to claim 25, wherein the first semiconductor layer has a thickness of 5 μm to 350 μm.

40. The semiconductor device according to claim 25, further comprising a second electrode defined on the second semiconductor layer and connected electrically to the MIS transistor structure.

41. The semiconductor device according to claim 25, wherein the first semiconductor layer and the second semiconductor layer are made of wide bandgap semiconductor.

42. A semiconductor device manufacturing method comprising the steps of:
defining a second conductivity type second semiconductor layer on one of the surfaces of a first conductivity type first semiconductor layer;
defining an MIS transistor structure in a surface portion on the side of the second semiconductor layer opposite to the first semiconductor layer;
selectively etching the other surface of the first semiconductor layer opposite to the second semiconductor layer to define a trench having a bottom portion reaching the second semiconductor layer; and
defining a first electrode to be in Ohmic contact with the second conductivity type region of the second semiconductor layer at least at the bottom portion of the trench and in Ohmic contact with the first semiconductor layer on the other surface of the first semiconductor layer so as to enter the trench.

43. The semiconductor device manufacturing method according to claim 42, wherein the step of defining the second semiconductor layer comprises the step of epitaxially growing the second semiconductor layer on the first semiconductor layer that is prepared as a substrate.

44. The semiconductor device manufacturing method according to claim 42, wherein the step of defining the second semiconductor layer comprises the steps of:
epitaxially growing the first semiconductor layer on a second conductivity type substrate;
epitaxially growing the second semiconductor layer on the first semiconductor layer; and
removing the second conductivity type substrate.

45. The semiconductor device manufacturing method according to claim 42, further comprising the step of thinning the first semiconductor layer from the other surface before the step of defining the trench.

46. The semiconductor device manufacturing method according to claim 45, wherein the step of thinning the first semiconductor layer comprises the step of polishing and finishing the other surface of the first semiconductor layer.

47. The semiconductor device manufacturing method according to claim 42, wherein the step of defining the first electrode comprises the step of laser-annealing and sintering the first electrode defined on the other surface of the first semiconductor layer.

48. A semiconductor device comprising:
a first conductivity type first semiconductor layer formed by epitaxial growth;
a second conductivity type second semiconductor layer formed on the first semiconductor layer by epitaxial growth;
an MIS transistor structure defined in a surface portion on the side of the second semiconductor layer opposite to the first semiconductor layer;
a trench defined selectively in the first semiconductor layer and having a bottom portion reaching the second semiconductor layer; and
a first electrode defined on a back surface of the first semiconductor layer such that the first electrode enters the trench, wherein
the second semiconductor layer has a second conductivity type region in a manner extending across a first portion exposed at the bottom portion of the trench and a second portion in contact with the first conductivity type layer, and
the first electrode is in Ohmic contact with the second conductivity type region at least at the bottom portion of the trench and in Ohmic contact with the first semiconductor layer.
